(19) United States
(12) Patent Application Publication
(10) Pub. No.: US 2025/0300064 A1
(43) Pub. Date: Sep. 25, 2025

(54) CAPACITOR FORMED IN INTERCONNECT LAYER

(71) Applicant: NXP USA, INC., AUSTIN, TX (US)

(72) Inventors: Asanga H. Perera, West Lake Hills, TX (US); Viet Thanh Dinh, Austin, TX (US); Mark Douglas Hall, Cary, NC (US); Kurt Hillman Junker, Chapel Hill, NC (US)

(21) Appl. No.: 18/611,778

(22) Filed: Mar. 21, 2024

(51) Int. Cl. H01L 23/522

(52) U.S. Cl. CPC H01L 23/5223; H10D 1/696

(57) ABSTRACT

A process for making a capacitor in an interconnect layer of a semiconductor die. The process includes forming interconnect structures that include portions located in a metal layer of the interconnect layer. The interconnect structures are laterally separated by dielectric material in the metal layer. Dielectric material of the metal layer is selectively removed to form an opening where a capacitor dielectric layer and then a conductive material are formed in the opening. The wafer is planarized to form a remaining structure in the metal layer. One electrode of the capacitor includes the remaining structure, and a second electrode of the capacitor includes the interconnect structure. A portion of the capacitor dielectric layer serves as a capacitor dielectric for the capacitor.

### BACKGROUND OF THE INVENTION

### Field of the Invention

This invention relates in general to capacitors formed in interconnect layers of semiconductor die.

### Description of the Related Art

Capacitors are utilized in the circuitry of electronic systems. For example, capacitors can be used as decoupling capacitors.

### BRIEF DESCRIPTION OF THE DRAWINGS

The present invention may be better understood, and its numerous objects, features, and advantages made apparent to those skilled in the art by referencing the accompanying drawings.

FIG. 1 is a partial cutaway side view of a wafer during a stage in the manufacture of a semiconductor die according to one embodiment of the present invention.

FIGS. 2-10 are partial cutaway side views of a wafer during various stages in the manufacture of a semiconductor die according to one embodiment of the present invention.

FIG. 11 is a circuit diagram of a decoupling capacitor according to one embodiment of the present invention.

The use of the same reference symbols in different drawings indicates identical items unless otherwise noted. The Figures are not necessarily drawn to scale.

### DETAILED DESCRIPTION

The following sets forth a detailed description of at least one mode for carrying out the invention. The description is intended to be illustrative of the invention and should not be taken to be limiting.

Described herein is a process for making a capacitor in an interconnect layer of a semiconductor die. The process includes forming interconnect structures that include portions located in a metal layer of the interconnect layer. The interconnect structures are laterally separated by dielectric material in the metal layer. Dielectric material of the metal layer is selectively removed to form an opening where a capacitor dielectric layer and then a conductive material are formed in the opening. The wafer is planarized to form a remaining structure in the metal layer. One electrode of the capacitor includes the remaining structure, and a second electrode of the capacitor includes the interconnect structure. A portion of the capacitor dielectric layer serves as a capacitor dielectric for the capacitor.

One advantage of such a process that may occur in some embodiments is that a remaining structure capacitor electrode can be formed in “unused space” of a metal layer of the interconnect layer with minimal changes to the processing of the wafer. For example, because the interconnect structures of the metal layer are formed first, the remaining structure can be formed in a space that is not occupied by interconnects of the metal layer. Furthermore, in some embodiments, the remaining structures can be formed with just one additional mask. In addition, with some embodiments where process manufacturing rules govern minimal lateral distances between two simultaneously formed interconnects in a metal layer, a remaining structure electrode may be formed closer to the opposing interconnect electrode than if the two interconnect electrodes were formed simultaneously in the metal layer.

In some embodiments, such a process may be beneficial in forming a decoupling capacitor. In some embodiments, the interconnect structure can be made to be coupled to one power supply rail and the remaining structure can be made to be coupled to another power supply rail to provide a decoupling capacitor between the two rails. Accordingly, with some embodiments, the decoupling capacitor can be implemented in “unused” space of an interconnect layer instead of being implemented in specifically designated areas of the die or instead of being implemented off die. Such a capacitor may be more easily added to different semiconductor circuit designs and save die space.

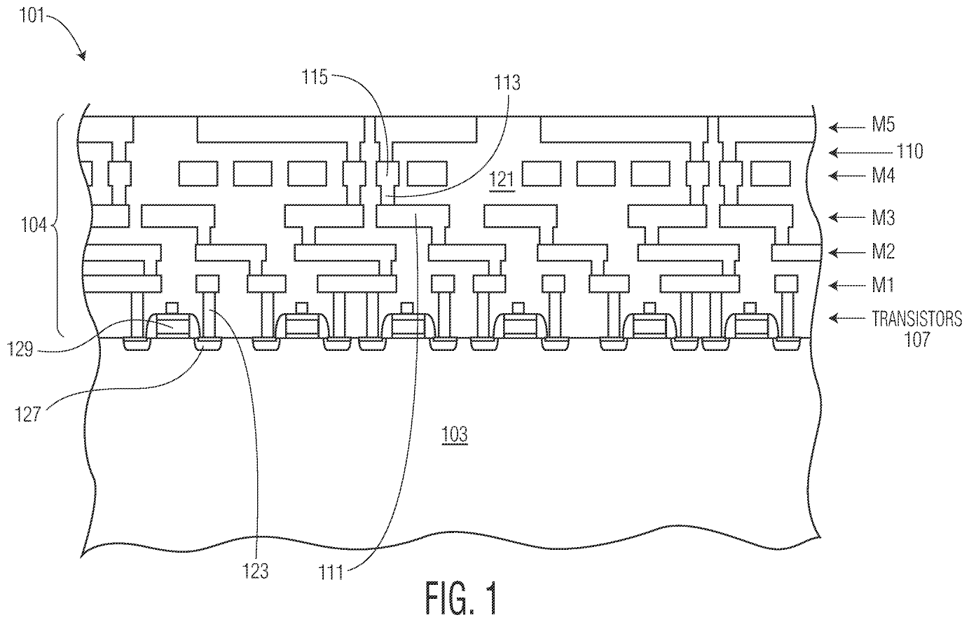

FIG. 1 is a cutaway side view of a wafer according to one embodiment of the present invention. Wafer 101 includes a substrate 103 that in one embodiment is made of monocrystalline silicon, but may be made of other types of semiconductor material (e.g., silicon germanium, silicon carbon, gallium nitride, or other III-V semiconductor material) in other embodiments. In the embodiment shown, substrate 103 has a bulk semiconductor configuration. In other embodiments, substrate 103 may have other configurations such an SOI (semiconductor-on-insulator) configuration. Substrate 103 may be formed from a slice of a semiconductor ingot. In some embodiments, substrate 103 may include epitaxial layers grown on the ingot slice. Not shown in FIG. 1 are dielectric materials in substrate 103 (e.g., such as isolation structures and buried oxide layers).

During wafer processing, semiconductor devices such as transistors, resistors, and diodes may be formed in substrate 103 by selectively doping regions of substrate 103 with conductivity dopants such as N-type dopants (arsenic and phosphorus) and P-type dopants (boron). In the example of FIG. 1, multiple transistors 107 are formed in substrate 103. In the embodiment shown, the transistors are field effect transistors with the source and drain regions (e.g., region 127) located in substrate 103 and the gates (e.g., gate 129) located on a gate dielectric above substrate 103. However, a wafer may include other types of semiconductor devices including other types of transistors in other embodiments.

Wafer 101 includes an interconnect layer 104 located over substrate 103. Interconnect layer 104 includes one or more metal layers with layers M1-M5 being shown in FIG. 1. As used herein, a “metal layer” of an interconnect layer is a layer that includes interconnects laterally separated by dielectric material where at least some of the interconnects of the metal layer provide both a horizontal and a vertical component for a conductive signal path or bias path between semiconductor device terminals of the semiconductor die and/or between at least one semiconductor device terminal and at least one external terminal (e.g., bond pad, bond post-not shown in FIG. 1) of the die. The interconnects are made of a type of conductive material (e.g., copper, gold, aluminum) and may include a conductive barrier material (e.g., tantalum, titanium, tantalum nitride, titanium nitride).

Interconnect layer 104 includes via layers (110) located in between the metal layers. The via layers include conductive vias (e.g., 113) for providing a vertical conductive path between an interconnect (e.g., 111) of one metal layer (e.g., M3) and an interconnect (e.g., 115) of another metal layer (e.g., M4). In one embodiment, the conductive vias are made of the same type of material as the interconnects. However, in other embodiments, the conductive vias may be made of a different type of conductive material. The via layers also include a dielectric material (e.g., oxide) that laterally separates the vias of each via layer.

In FIG. 1, the dielectric material 121 of the via layers and metal layers is shown as a continuous material throughout interconnect layer 104. However, dielectric material 121 is formed in layers as part of forming the metal layers and the intervening via layers. Interconnect layer 104 also includes contacts (e.g., contact 123) for providing a conductive path from terminals of the semiconductor devices (e.g., region 127) to the interconnects of metal layer M1.

In one embodiment, metal layers M2-M5 and the intervening via layers are formed by a dual-damascene process where the interconnects of a metal layer and the conductive vias of the underlying via layer are contiguous and formed with the same process steps. In some examples of a process for forming a metal layer, a layer of dielectric material (e.g., an oxide formed by a tetraethyl orthosilicate (TEOS) process) is formed on wafer 101. The layer is double patterned to form the openings for the conducive vias and the openings for the interconnects. A barrier layer material (e.g., titanium, tantalum, titanium nitride, tantalum nitride) is formed over wafer 101 followed by a second type of conductive material (e.g., copper or gold). Wafer 101 is then planarized to form contiguous interconnect/via structures. FIG. 1 shows the stage of manufacture after metal layer M5 and the underlying via layer 110 have been formed.

The metal layers and via layers may be formed by other processes in other embodiments. For example, the via layers and metal layers may be separately formed. In one such example, a dielectric layer for a via layer is formed over the wafer. Photo-lithographically defined openings are formed in the dielectric layer. Afterwards, a barrier layer and a second conductive layer are sequentially formed on the wafer and then planarized. The same process is then used to form the metal layer. However, other processes may be used in other embodiments.

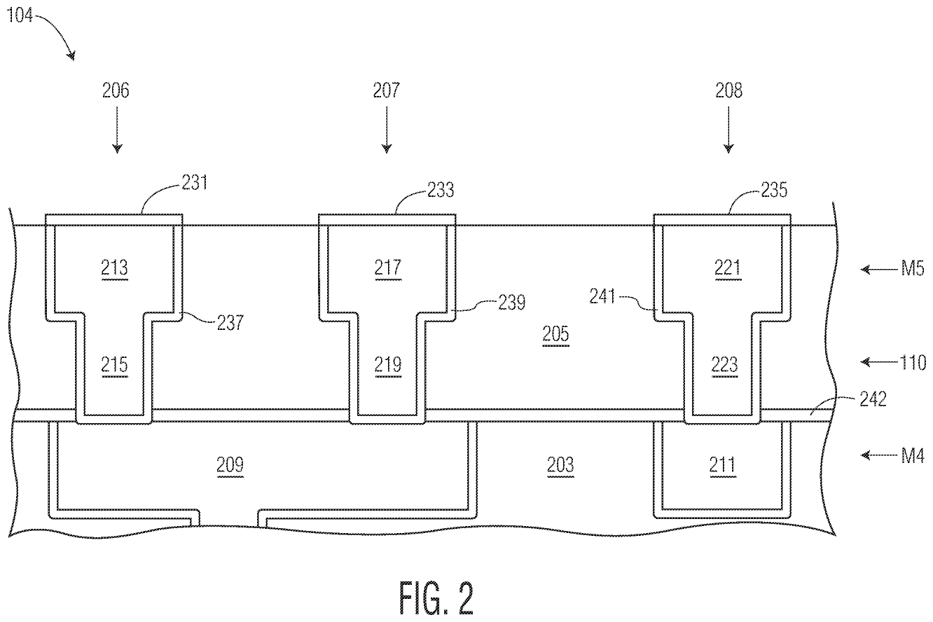

FIG. 2 is a partial cutaway side view of interconnect layer 104 after the stage of FIG. 1. Shown in FIG. 2 are views of metal layer M4, metal layer M5, and intervening via layer 110. Metal layer M4 includes interconnect structures 209 and 211 that are separated by a dielectric 203. In the embodiment of FIG. 2, interconnect structures 209 and 211 include underlying via portions (not shown for structure 211) that are electrically connected to underlying interconnects in metal layer M3 (not shown in FIG. 2).

Interconnect structures 206, 207, and 208 each include interconnects 213, 217, and 221, respectfully, located in metal layer M5 and vias 215, 219, and 223, respectively, located in via layer 110. The interconnects and vias also include exterior barrier layer surfaces. For example, the portions of interconnect structure 206 include portions of barrier layer 237, the portions of interconnect structure 207 include portions of barrier layer 239, and the portions of interconnect structure 208 include portions of barrier layer 241. Interconnect structures 206-208 are laterally separated from each other by dielectric material 205 of metal layer M5 and of via layer 110.

The dielectric material of interconnect layer 104 includes a dielectric copper diffusion layer 242 located over metal layer M4. In one embodiment, layer 242 is made of silicon nitride or silicon carbon nitride, but may be made of other types of dielectric material in other embodiments. Openings are formed in layer 242 so that the barrier layer surface of vias 215, 219, and 223 of via layer 110 can contact the interconnects of metal layer M4.

As shown in FIG. 2, capping layers 231, 233, and 235 are selectively grown on interconnects 213, 217, and 221, respectively, by a self-aligned electroless plating process. In one embodiment, layers 231, 233 and 235 are made of a cobalt based material. However, layers 231, 233, and 235 may be made of other types of materials that can be selectively grown and that are etch selectable with respect to dielectric material 205. Capping layers 231, 233, and 235 act as an etch mask in subsequent processes and also act as a copper diffusion barrier.

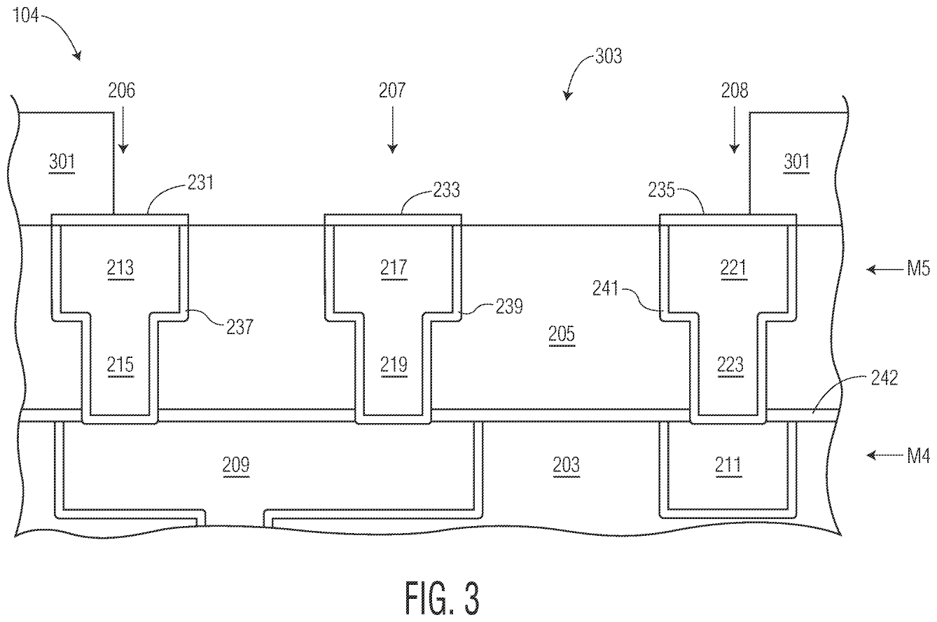

FIG. 3 is a partial cutaway side view of interconnect layer 104 after a patterned mask 301 is formed on wafer 101 with a photo-lithographically defined opening 303 to expose the top surfaces of layers 231, 233, and 235 and portions of dielectric material 205. In one embodiment, mask 301 is made of photoresist, however, other types of mask materials may be used in other embodiments.

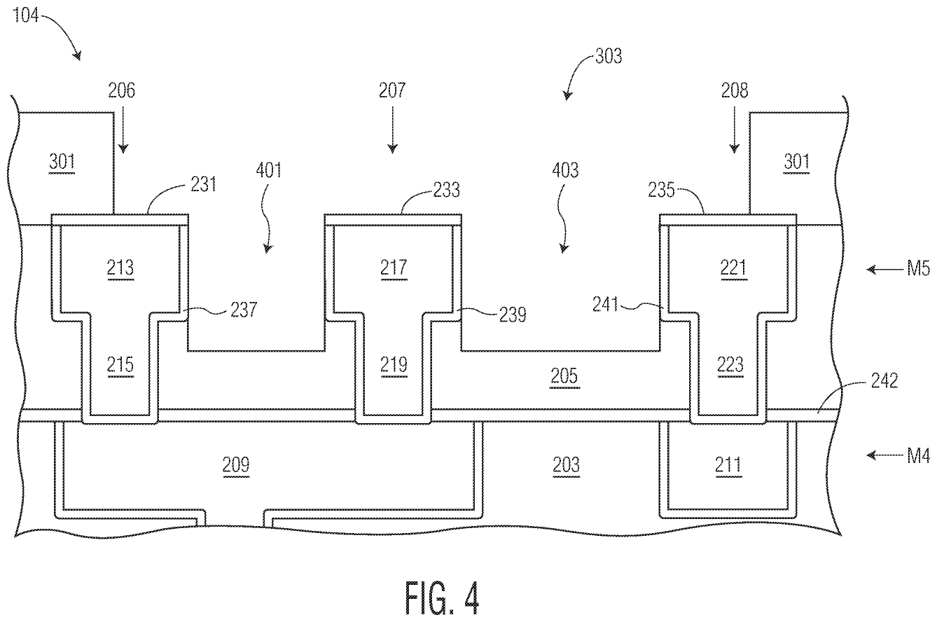

FIG. 4 is a partial cutaway side view of interconnect layer 104 after openings are formed in dielectric material 205. Openings 401 and 403 are formed by a timed anisotropic etch with an etch chemistry that is selective to the materials of mask 301, layers 231, 233, and 235, and barrier layers 237, 239, and 241 and selective with respect to dielectric material 205. In the embodiment shown, the timed etch removes dielectric material 205 to a level below the bottom of interconnects 213, 217, and 221. Although in other embodiments, openings 401 and 403 may be etched to different levels including to the top surface of layer 242 or to the top surface of interconnect structure 209.

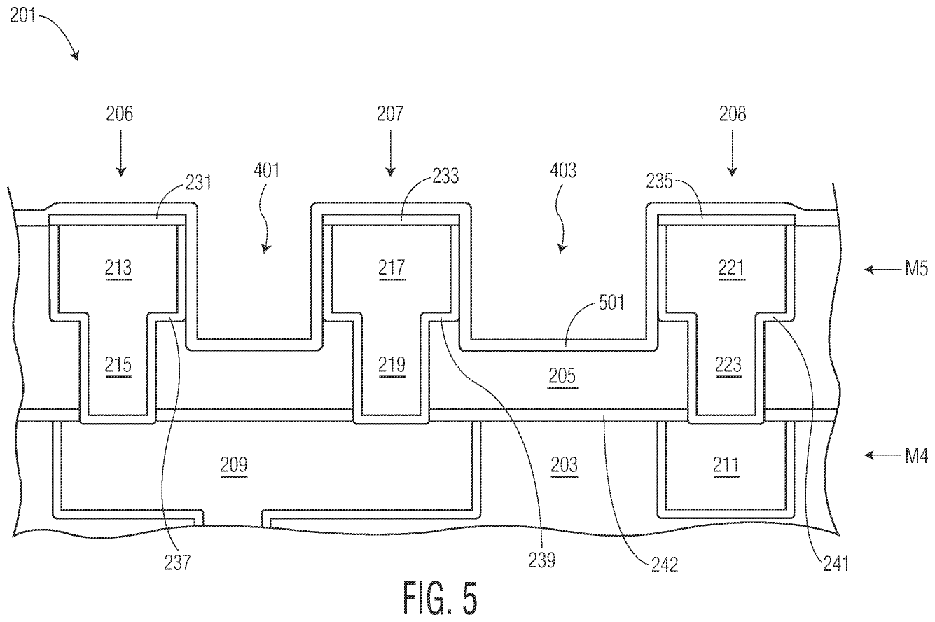

FIG. 5 is a partial cutaway side view of interconnect layer 104 after mask 301 is removed and a layer 501 of a capacitor dielectric material is deposited over wafer 101 including in openings 401 and 403. In one embodiment, layer 501 is made of silicon oxide and has a thickness of 5-30 nm, but may be of other thicknesses and be made of other types of dielectric materials in other embodiments, including high-K dielectric materials such as e.g., Al₂O₃, HfO₂, BaSm₂Ti₄O₁₂, Sm₂TiO₇. In an embodiment shown below, the thickness of dielectric layer 501 defines the distance between the electrodes of the subsequently formed capacitor.

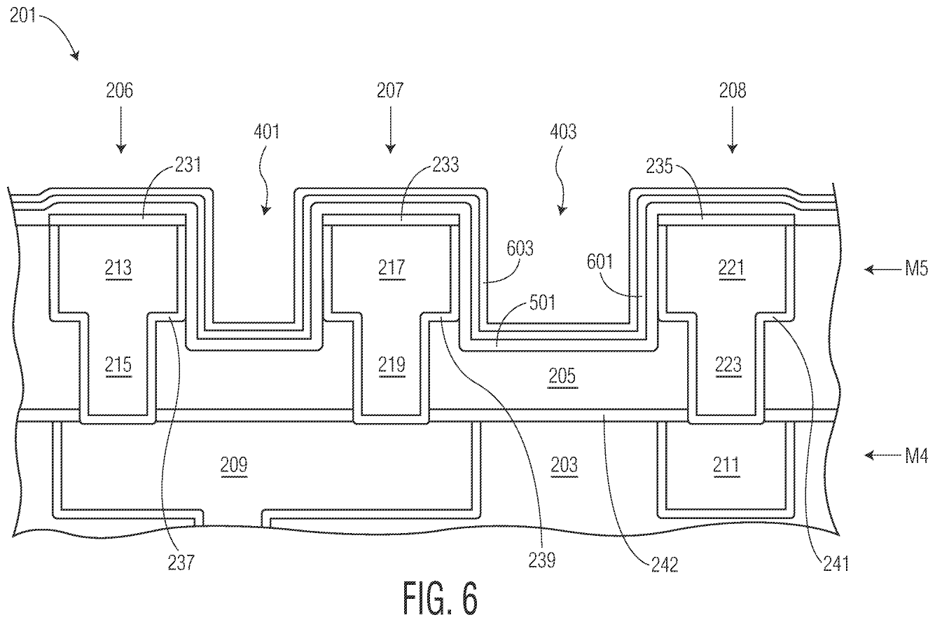

FIG. 6 is a partial cutaway side view of interconnect layer 104 after a conductive barrier layer 601 and seed layer 603 are formed over wafer 101 including in openings 401 and 403. In one embodiment, barrier layer 601 is made of tantalum, titanium, tantalum nitride or titanium nitride, but may be made of other types of barrier materials in other embodiments.

Seed layer 603 is formed of a metal (e.g., copper, gold) on layer 601 by sputtering, atomic layer deposition, seedless plating, or other methods.

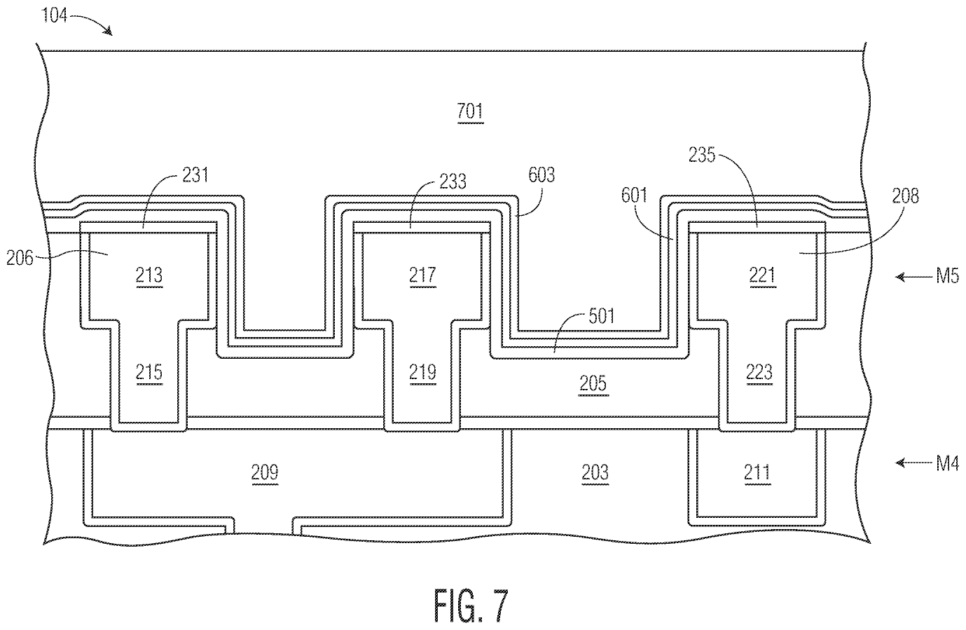

FIG. 7 is a partial cutaway side view of interconnect layer 104 after a metal layer 701 has been formed on wafer 101 to fill the remaining portions of openings 401 and 403. In one embodiment, layer 701 is made of copper and is formed by a plating process using seed layer 603 as a cathode plating layer. However, layer 701 may be made by other processes and/or be made of other types of materials in other embodiments.

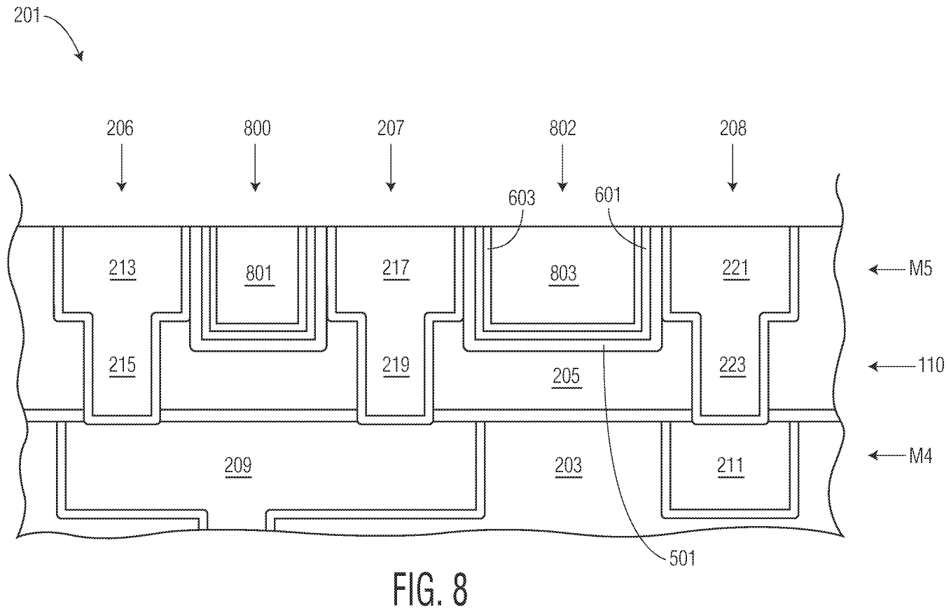

FIG. 8 is a partial cutaway side view of interconnect layer 104 after wafer 101 has been planarized (e.g., with chemical mechanical polishing (CMP)) to remove the conductive material of layers 601, 603 and 701 outside of openings 401 and 403 to form remaining structures 800 and 802. As shown in FIG. 8, remaining structure 800 includes a portion 801 of layer 701, a portion of seed layer 603, and a portion of barrier layer 601. Remaining structure 802 includes a portion 803 of layer 701, a portion of seed layer 603, and a portion of barrier layer 601. The planarization also removes the portion of capacitive dielectric layer 501 located outside of openings 401 and 403 and removes capping layers 231, 233 and 235.

As shown in FIG. 8, interconnects 213, 217, and 221 are separated from remaining structures 800 and 802 by remaining portions of dielectric layer 501. In subsequent processes, remaining structures 800 and 802 will be electrically connected together to form one electrode of a capacitor and interconnects 213, 217, and 221 are or will be electrically connected together to form the other electrode of the capacitor. In the embodiment shown, the capacitance of the capacitor is dependent upon the amount of surface area of both electrodes in contact with the remaining capacitive dielectric material layer 501, the thickness of dielectric material layer 501, and the dielectric constant of the type of dielectric material of dielectric layer 501.

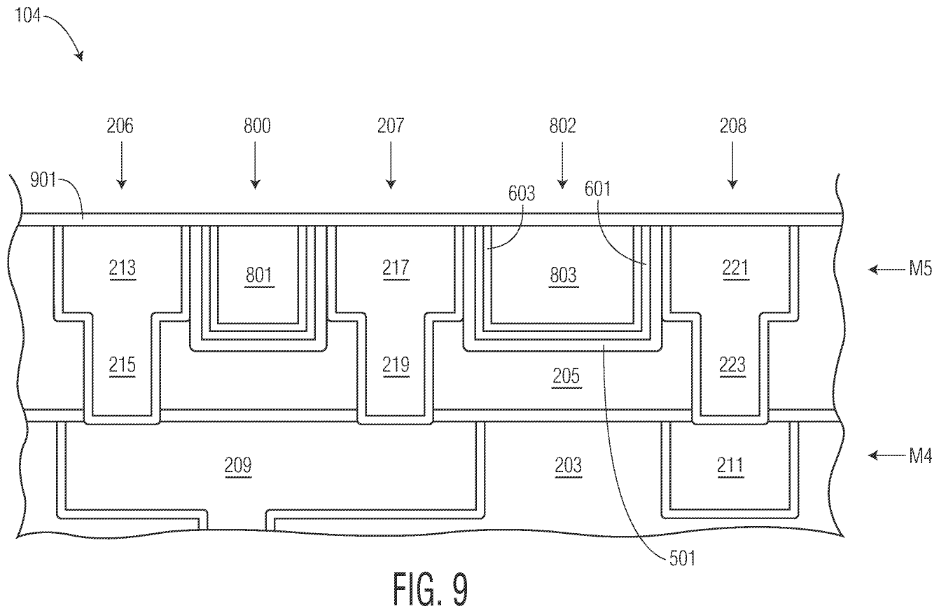

FIG. 9 is a partial cutaway side view of interconnect layer 104 after a diffusion barrier layer 901 is formed on the planarized surface of wafer 101. In one embodiment, layer 901 is made of a type of dielectric material such as silicon nitride or silicon carbon nitride to prevent diffusion of copper in interconnect layer 104. However, other types of dielectric materials may be used in other embodiments.

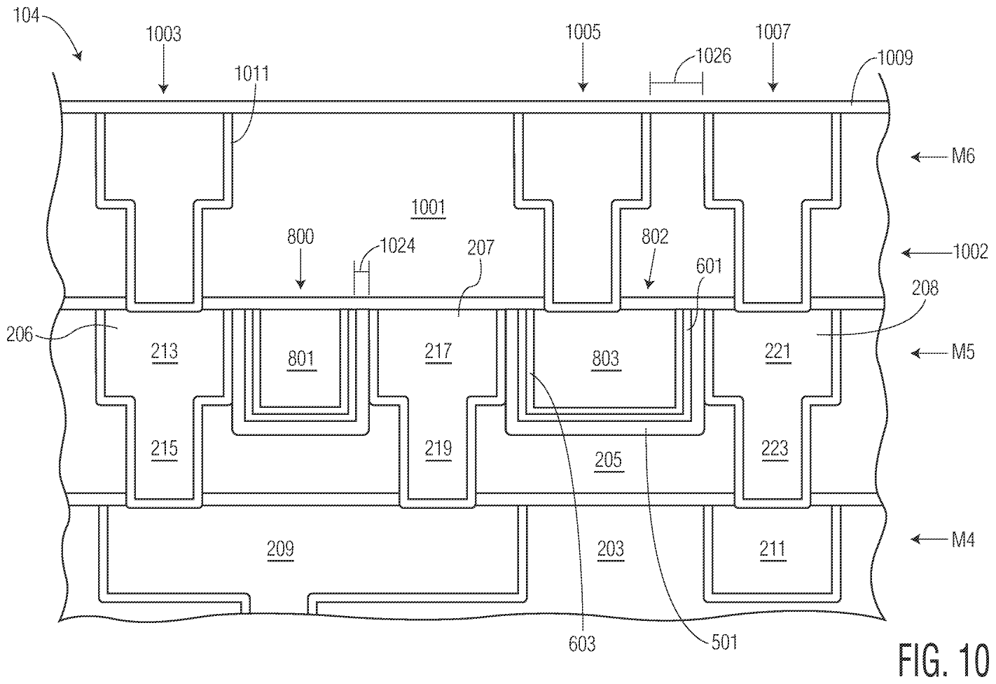

FIG. 10 is a partial cutaway side view of interconnect layer 104 after an additional metal layer M6 and via layer 1002 are formed on wafer 101. Metal layer M6 and via layer 1002 each include portions of interconnect structures 1003, 1005, and 1007 and portions of dielectric material 1001. A dielectric diffusion layer 1009 is formed on metal layer M6.

In the embodiment shown, interconnect structure 1003 is in electrical contact with interconnect structure 206. Interconnect structure 1005 is in electrical contact with remaining structure 802, and interconnect structure 1007 is in electrical contact with interconnect structure 208.

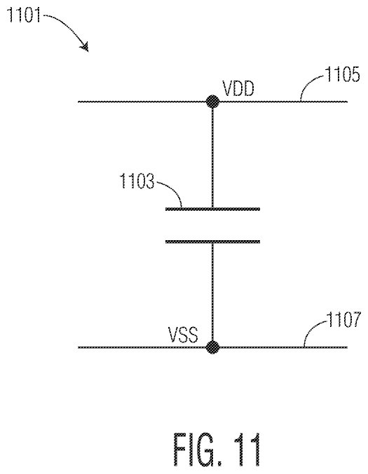

In one embodiment, interconnects 213, 217, and 221 may be part of one voltage supply rail (e.g., VDD voltage supply rail 1105 in FIG. 11) and remaining structures 800 and 802 could be connected to another voltage supply rail (VSS voltage supply rail 1107 in FIG. 11) to provide a decoupling capacitor between the two voltage supply rails. See FIG. 11 showing a decoupling capacitor 1103 with one electrode connected to VDD voltage supply rail 1105 and another electrode connected to VSS voltage supply rail 1107. A decoupling capacitor is a capacitor that is connected between two nodes to decouple the AC current from the DC current where the decoupling capacitor allows the AC current on one node (e.g., VDD voltage supply rail 1105) to pass through to the other node (e.g., VSS voltage supply rail 1107). In some instances, a decoupling capacitor may be referred to as a bypass capacitor. Decoupling capacitors may be used to reduce noise on a voltage supply rail to keep the supply voltage within tolerance even with rapid changes in current draw. Decoupling capacitors placed between a VDD rail and a VSS rail can function to provide local energy sources to minimize VDD rail voltage drop during circuit function.

One advantage of using the above processes to make decoupling capacitors is that the capacitance value of a decoupling capacitor does not have to be precise for the circuit to operate effectively. Accordingly, the decoupling capacitor can be located wherever there is space in the interconnect layer depending upon the design. Because the capacitance of a decoupling capacitor does not have to be precise, the lateral area of the remaining electrodes (e.g., 802) does not have to be well defined, thereby simplifying mask definition. Furthermore, the decoupling capacitance connected between voltage supply rails may be distributed at various locations of the supply rail. Accordingly, a decoupling capacitor can be made at multiple locations in an interconnect layer where space is available.

The processes described herein may be used to form other types of capacitors in other embodiments including, e.g., smoothing capacitors for voltage regulators, sampling capacitors for sample and hold circuits, and capacitors for matching networks. In some embodiments of RF circuit applications, adding capacitance as described herein can improve the quality factor (i.e., maintain lower energy dissipation and higher energy storage), provide a superior cut-off frequency, and provide a better matching due to lateral coupling.

One advantage of the processes described herein for making a capacitor is that the lateral distance between two capacitor electrode structures in an interconnect layer can be made closer together than if the two electrode structures were formed simultaneously in the same metal layer. For example, referring back to FIG. 10, the lateral distance 1024 between electrode remaining structure 800 and electrode interconnect structure 207 in metal layer M5 is the thickness of capacitor dielectric layer 501. In one embodiment, this thickness is in the range of 5 to 30 nm.

If both electrodes included interconnects that were formed simultaneously with other interconnects of a metal layer, then the lateral spacing between the two interconnects would be limited by process spacing rules for forming laterally adjacent interconnects. For example, process spacing rules may limit the lateral spacing to no closer than a specific width (e.g., 15 nm in some advanced technologies, but the minimum lateral spacing may be wider in other technologies including less advanced technologies). In the embodiment of FIG. 10, width 1026 between structures 1005 and 1007 is the minimum lateral spacing between any two interconnects in a metal layer on wafer 101. Using processes described herein, it may be possible to decrease the lateral spacing between capacitive electrodes by using a thinner capacitor dielectric layer (e.g., layer 501). The ability to more closely space the capacitor electrodes in some embodiments not only allows for an increased capacitance, but it also allows for the capacitive electrodes to be more compact. For example, in FIG. 10, electrode structure 800 is laterally adjacent to both structures 206 and 207 wherein the overall lateral spacing between the three structures is less than if the three structures were formed simultaneously.

Another advantage of the processes of at least some embodiments described herein is that the capacitive dielectric layer (e.g., 501) can be a different type of dielectric material than the other types of dielectric material (e.g., 205) of the interconnect layer. For example, the capacitive dielectric layer may have a higher (or lower) dielectric constant than material 205.

After the stage of manufacture shown in FIG. 10, subsequent processes may be performed on wafer 101. For example, additional metal layers and via layers may be formed over metal layer M6. After the formation of the final metal layer (M6 or higher) of interconnect layer 104, die terminals (e.g., bumps, pads, pillars-not shown) would be formed over the final metal layer where each die terminal is electrically connected to an interconnect on the final metal layer. Afterwards, wafer 101 is singulated into multiple semiconductor die, where each die includes at least one capacitor including electrode structures similar to structures 206, 207, 208, 800, and 802. The die are then protected in semiconductor packages that can be implemented in electronic systems such as e.g., RF communications systems, motor controllers, automotive electronics systems, computers, industrial equipment, appliances, and cellular phones.

In some embodiments, remaining capacitive electrode structures (similar to structures 800 and 802) may be located in other parts of metal layer M5 or in other metal layers of wafer 101.

Also, the processes described herein can be used to make a multi-metal layer capacitor. For example, referring to FIG. 8, an interconnect structure (e.g., 209) in metal layer M4 may extend across the entire capacitor structure. In such an embodiment, the opening in dielectric material 205 would extend to the top surface of this interconnect structure of metal layer M4 where capacitor dielectric would be formed on the top surface of the interconnect structure and where the interconnect structure would be part of a capacitor electrode. In some embodiments, the interconnect/via structure (e.g., 206) in the immediately above via layer (110) and metal layer (M5) would completely surround the perimeter of the top surface of the interconnect structure of the lower metal layer (M4). In embodiments where the etching includes an isotropic etch, all of the dielectric material within the surrounding interconnect/via structure would be removed where the entire surrounding structure and the interconnect structure of the lower metal layer (M4) would be part of a capacitive electrode.

As disclosed herein, a first structure is “directly over” a second structure if the first structure is located over the second structure in a line having a direction that is perpendicular with a generally planar major side of the wafer or substate. For example, in FIG. 10, structure 1007 is directly over structure 211. Structure 1007 is not directly over structure 209. As disclosed herein, a first structure is “directly beneath” or “directly under” a second structure if the first structure is located beneath the second structure in a line having a direction that is perpendicular with a generally planar major side of the wafer or substrate. For example, in FIG. 10, structure 209 is directly beneath structure 1003. Structure 209 is not directly beneath structure 1007. One structure is “directly between” two other structures in a line if the two structures are located on opposite sides of the one structure in the line. For example, in FIG. 10, remaining structure 800 is located directly between interconnect 213 and interconnect 217 in a line in the cut away side view of FIG. 10. Structure 209 is not located directly between structures 1003 and 1005. A first structure is “directly lateral” to a second structure if the first structure and second structure are located in a line having a direction that is parallel with a generally planar major side of the wafer or substrate. For example, structure 1003 and structure 1005 are directly lateral to each other. One structure is “directly laterally between” two other structures if the two structures are located on opposite sides of the one structure in a line that is parallel with a generally planar major side of the wafer or substrate. For example, in FIG. 10, structure 802 is located directly laterally between structure 206 and structure 208. A surface is at a “higher elevation” than another surface, if that surface is located closer to the top of the active side of a wafer or die in a line having a direction that is perpendicular with the generally planar major side of the wafer or die. In the views of FIGS. 1-10, the active side of the wafer is the top side of the Figures. For example, structure 1003 is at a higher elevation than structure 211.

In some embodiments, a method includes forming a first interconnect structure including a first portion located in a first metal layer of an interconnect layer of a wafer, the first portion directly laterally separated from other interconnect structures in the first metal layer by dielectric material of the first metal layer; after the forming the first interconnect structure, selectively removing a portion of the dielectric material directly laterally adjacent to the first portion to form an opening; forming a dielectric layer on the wafer including on a sidewall of the opening directly laterally adjacent to the first portion; forming conductive material on the wafer, the conductive material filling the opening; and planarizing the wafer, wherein the planarizing removes the conductive material above the opening to form a remaining portion of the conductive material in the opening, at least a portion of the remaining portion is located in the first metal layer. A first electrode of a capacitor includes the first portion and a second electrode of the capacitor includes the remaining portion, a capacitor dielectric of the capacitor includes a portion of the dielectric layer located directly laterally between the first portion and the remaining portion.

In other embodiments, a method includes forming a first interconnect structure including a first portion located in a first metal layer of an interconnect layer of a wafer, the first portion directly laterally separated from other interconnect structures in the first metal layer by dielectric material of the first metal layer; after the forming the first interconnect structure, selectively removing a portion of the dielectric material directly laterally adjacent to the first portion to form an opening; forming a dielectric layer on the wafer including on a sidewall of the opening directly laterally adjacent to the first portion; forming conductive material on the wafer, the conductive material filling the opening; planarizing the wafer, wherein the planarizing removes the conductive material above the opening to form a remaining portion of the conductive material in the opening, at least a portion of the remaining portion is located in the first metal layer; and singulating the wafer into a plurality of semiconductor die, wherein a first semiconductor die of the plurality of semiconductor die includes a decoupling capacitor, the decoupling capacitor includes a first electrode that includes the first portion and a second electrode that includes the remaining portion, a capacitor dielectric of the decoupling capacitor includes a portion of the dielectric layer located directly laterally between the first portion and the remaining portion.

Features specifically shown or described with respect to one embodiment set forth herein may be implemented in other embodiments set forth herein.

While particular embodiments of the present invention have been shown and described, it will be recognized to those skilled in the art that, based upon the teachings herein, further changes and modifications may be made without departing from this invention and its broader aspects, and thus, the appended claims are to encompass within their scope all such changes and modifications as are within the true spirit and scope of this invention.

What is claimed is:

1. A method comprising:
forming a first interconnect structure including a first portion located in a first metal layer of an interconnect layer of a wafer, the first portion directly laterally separated from other interconnect structures in the first metal layer by dielectric material of the first metal layer;
after the forming the first interconnect structure, selectively removing a portion of the dielectric material directly laterally adjacent to the first portion to form an opening;
forming a dielectric layer on the wafer including on a sidewall of the opening directly laterally adjacent to the first portion;
forming conductive material on the wafer, the conductive material filling the opening;
planarizing the wafer, wherein the planarizing removes the conductive material above the opening to form a remaining portion of the conductive material in the opening, at least a portion of the remaining portion is located in the first metal layer;
wherein a first electrode of a capacitor includes the first portion and a second electrode of the capacitor includes the remaining portion, a capacitor dielectric of the capacitor includes a portion of the dielectric layer located directly laterally between the first portion and the remaining portion.

2. The method of claim 1 wherein the selectively removing a portion of the dielectric material exposes a conductive sidewall of the first portion.

3. The method of claim 1 wherein:
the forming a first interconnect structure including a first portion located in a first metal layer includes forming a second interconnect structure including a first portion located in a first metal layer, the first portion of the first interconnect structure and the first portion of the second interconnect structure are directly laterally separated by the dielectric material;
the opening is directly laterally adjacent to the first portion of the second interconnect structure;
the first electrode includes the first portion of the second interconnect structure.

4. The method of claim 1 further comprising:
after the forming the interconnect structure and prior to the selectively removing, selectively forming a capping layer on the first interconnect structure.

5. The method of claim 4 wherein the capping layer is formed by an electroless plating process.

6. The method of claim 4 wherein the selectively removing includes using an etch chemistry to remove the dielectric material, wherein the etch chemistry is selective to material of the capping layer.

7. The method of claim 1 wherein the capacitor is characterized as a decoupling capacitor.

8. The method of claim 7 further comprising:
singulating the wafer into a plurality of semiconductor die;
wherein the first portion of the first interconnect structure is connected to a first voltage supply rail and the remaining portion is connected to a second voltage supply rail.

9. The method of claim 1 further comprising singulating the wafer into a plurality of semiconductor die.

10. The method of claim 9 wherein:
a first semiconductor die includes the capacitor;
each of the other of the plurality of semiconductor die includes a capacitor with a first electrode including a portion located in the first metal layer and being a portion of an interconnect structure formed simultaneously with first interconnect structure,
the capacitor of each of the other of the plurality of semiconductor die including a second electrode that includes a portion located in the first metal layer and formed simultaneously with the remaining portion;
the capacitor of each of the other of the plurality of semiconductor die including a capacitor dielectric including a portion of the dielectric layer located directly laterally between the portion located in the first metal layer and being a portion of an interconnect structure formed simultaneously with first interconnect structure and the portion located in the first metal layer and formed simultaneously with the remaining portion.

11. The method of claim 1 wherein the forming conductive material on the wafer includes forming a conductive barrier layer on the dielectric layer followed by forming a second type of conductive material on the wafer.

12. The method of claim 11 wherein the forming the second type of conductive material includes forming a seed layer of the second type of conductive material on the wafer followed by an electroplating process to form a further amount of the second type of conductive material.

13. The method of claim 1 further comprising:
after the planarizing the wafer, forming a second interconnect structure and a third interconnect structure, the second interconnect structure including a first portion in a higher metal layer to the first metal layer, the second interconnect structure electrically connected to the first interconnect structure, the third interconnect structure including a first portion in the higher metal layer, the third interconnect structure electrically connected to the remaining portion.

14. The method of claim 1 wherein the forming a first interconnect structure includes planarizing the wafer to define a top surface of the first interconnect structure and a top surface of the portion of the dielectric material directly laterally adjacent to the first portion of the first interconnect structure.

15. The method of claim 1 wherein the forming a first interconnect structure including a first portion located in a first metal layer includes simultaneously forming a plurality of interconnect structures including portions in the first metal layer, wherein a minimum directly lateral spacing between any two interconnect structures of the plurality of interconnect structures is a first width, wherein a closest directly lateral distance between the first portion and the remaining portion is less than the first width.

16. The method of claim 1 wherein the first interconnect structure includes a via structure located directly under the first portion.

17. A method comprising:
forming a first interconnect structure including a first portion located in a first metal layer of an interconnect layer of a wafer, the first portion directly laterally separated from other interconnect structures in the first metal layer by dielectric material of the first metal layer;
after the forming the first interconnect structure, selectively removing a portion of the dielectric material directly laterally adjacent to the first portion to form an opening;
forming a dielectric layer on the wafer including on a sidewall of the opening directly laterally adjacent to the first portion;
forming conductive material on the wafer, the conductive material filling the opening;
planarizing the wafer, wherein the planarizing removes the conductive material above the opening to form a remaining portion of the conductive material in the opening, at least a portion of the remaining portion is located in the first metal layer;
singulating the wafer into a plurality of semiconductor die, wherein a first semiconductor die of the plurality of semiconductor die includes a decoupling capacitor, the decoupling capacitor includes a first electrode that includes the first portion and a second electrode that includes the remaining portion, a capacitor dielectric of the decoupling capacitor includes a portion of the dielectric layer located directly laterally between the first portion and the remaining portion.

18. The method of claim 17 wherein the selectively removing a portion of the dielectric material exposes a conductive sidewall of the first portion.

19. The method of claim 17 wherein the first electrode is configured to be biased by a first voltage supply rail and the second electrode is configured to be biased by a second voltage supply rail.

20. The method of claim 17 further comprising:
after the forming the first interconnect structure and prior to the selectively removing, selectively forming a capping layer on the first interconnect structure.
